(19) United States
(12) Patent Application Publication
(10) Pub. No.: US 2026/0364700 A1
(43) Pub. Date: Nov. 19, 2026

(54) APPARATUS WITH AN IMPROVED HOLD-DOWN DEVICE

(71) Applicant: BESI SWITZERLAND AG, Steinhausen (CH)

(72) Inventor: Rene KROEHNERT, Steinhausen (CH)

(21) Appl. No.: 19/478,248

(22) PCT Filed: Apr. 24, 2024
(86) PCT No.: PCT/IB2024/053983

§ 371 Date: Jan. 12, 2026

(30) Foreign Application Priority Data
Apr. 24, 2023 (DE) 10 2023 110 438.1

(51) Int. Cl. B23K 3/08; B23K 3/06; H10W 70/04

(52) U.S. Cl. CPC B23K 3/087; B23K 3/0623; H10W 70/04

(57) ABSTRACT

Apparatus (100, 101, 102) for processing a substrate (300) in a process chamber (400) wherein the apparatus (100, 101, 102) comprising a hold-down device (500, 501, 502) arranged to exert, in use, a hold-down force on at least a portion of the substrate (300). The processing chamber comprising a hold-down opening (270) for receiving an actuator member (520) of the hold-down device, whereby the hold-down force is directly exerted, in use, from outside the processing chamber (400).

### TECHNICAL FIELD

The present invention relates to an apparatus for processing a substrate, such as a lead frame. The invention further relates to an apparatus for dispensing solder onto a substrate. Further, the invention relates to an apparatus for distributing solder on a substrate. The invention also relates to an apparatus for bonding a component with a substrate.

### STATE-OF-THE-ART

From the state pf the art, various apparatus for processing a substrate are well-known
DE 10 2014 116 939 A1 discloses a hold-down device for holding down substrate locations of a substrate which comprises a plate with a central recess which makes at least one substrate location accessible for bonding dies, and with two arranged on both sides next to the middle of the central recess, further recesses, a hold-down plate with a recess and hold-down webs, a first and second pneumatic drive and pressure lines for supplying a compressed gas to the pressure chambers of the pneumatic drives. Each pneumatic drive comprises a cylinder and a drive element, between which a pressure chamber is formed. The cylinder of the first pneumatic drive is fastened over the one further recess and the cylinder of the second pneumatic drive is fastened over the other further recess.
U.S. Pat. No. 5,878,939A describes producing separate measured portions of liquid solder, solid solder in the form of wire or rod which is guided through the longitudinal bore of a guide tube. A zone including the end of the tube is heated above the solder's melting temperature, in order to liquefy the solder. By contrast, an adjacent zone of the guide tube is cooled, whereby a positionally stable temperature transition is maintained in the tube. Thereby the amount of molten solder available above a narrowed outlet is controlled. A drive mechanism advances the solder step by step so that the solid solder acts as a piston to eject portions of liquid solder through the aforesaid outlet. A suitable apparatus for applying portions of solder to a substrate can be raised and lowered. At its base it has a moulding die connected to the outlet that can be set down upon the substrate and has a moulding cavity open on its underside. This determines and restricts the surface wetted by the liquid solder on the substrate. The main application is the bonding of semiconductor chips (components) by soft-soldering.
CH 704991 A1 describes a method involving dispensing at least one solder portion on surface of substrate e.g. lead frame, lowering pin into solder portion until pin touches substrate surface, applying predetermined force to pin so that pin presses against the substrate. The ultrasonic sound is applied to pin in such a way that ultrasonic waves are produced in pin which are directed perpendicularly or angularly in relation to substrate surface. The pin is moved along a predetermined path which extends parallel to the substrate surface. The pin is lifted until pin has been severed from solder portion. A method for mounting semiconductor chips (components) on a substrate are also described.

In general, for reliable, repeatable and reproducible processing of substrates, one or more operations are preferably performed in a controlled processing environment. Conventional apparatus may provide this by enclosing the processing position during the processing. Hold-down devices (or down holders) may also be used to retain substrates against a support during at least a part of a processing step. However, inaccuracies or damages are introduced, if different parts of the hold-down device being non-uniformly heated, particularly if processed at a temperature that is much higher than the ambient temperature of the apparatus

Therefore, a part of a hold-down device is usually integrated into an upper wall of a chamber for a process environment. If this upper wall is designed to be opened for offline access, for example, by comprising one or more lids or hatches, the hold-down force exerted during use is substantially determined or influenced by the force required to close the one or more lids, and/or a closing force of the one or more lids is larger than the hold-down force.

### OBJECT OF THE INVENTION

The object of the present invention is to provide an apparatus suitable for processing substrates, which has an improved hold-down device allowing the hold-down forces to be regulated during operation.

### SOLUTION

For solving the problem, a technical apparatus according to the independent claim is provided. Technically advantageous embodiments are the subject of the dependent claims, the description and the figures.

### DESCRIPTION OF THE INVENTION

According to one aspect, the problem is solved by providing an apparatus for processing a substrate.

Such an apparatus is, for example, a chip processing apparatus or an apparatus for processing semiconductor dies. In general, such an apparatus provides a process environment in a process chamber that is suitable for processing a substrate, and the substrate is arranged for processing in the processing environment.

Within the scope of this disclosure, “processing” refers to any action that can be performed on or with a substrate. In the context of the invention, “processing” also includes individual process steps, entire processes, or sequences such as measurement or inspection, solder application, solder delivery, solder forming, solder pre-pressing, bonding a component, inspecting a component, inspecting a substrate, inspecting a previously bonded semiconductor wafer, inspecting a holder, inspecting a previous process step, or inspecting before a subsequent process step.

In accordance with the invention, successive individual process steps, processes, or sequences can be performed at the same processing position, at different processing positions in the same apparatus, at processing positions in different apparatuses, or any combination thereof.

The processing chamber of the apparatus comprises an chamber upper wall extending along a first axis and along a second axis, wherein the second axis is perpendicular to the first axis.

The substrate is arranged during use in such a way that it can be processed at a first processing position.

Suitable substrates for processing are generally all objects that have at least one surface to be processed. Suitable substrates for processing are, for example, metallic substrates, also indicated as leadframes, on which components are soldered onto chip islands arranged one behind the other and preferrably next to each other. However, the invention is not limited to lead frames—the one or more substrates are preferrably any object with at least one bondable surface. The one or more substrates can also be indicated as one or more media.

The component is any object with at least one bondable surface, such as a semiconductor wafer, chip, integrated circuit, or substrate. Components can be any form, such as rectangular, square, or round.

The apparatus comprises a hold-down device which, in use, exerts a hold-down force on at least a portion of the substrate along a third axis perpendicular to a first axis and a second axis, against a mounting from which the substrate is upheld at the first processing position or against a support on which the substrate rests at the first processing position.

This has the advantage that during processing, the substrate is pressed rigidly against a suitable mounting, preferrably against a suitable support, which is arranged for receiving the substrate before processing and to uphold or provide the substrate during processing.

In embodiments of an apparatus, the mounting or support is substantially either a fixed mounting or fixed support or a movable mounting or movable support, which in both cases is preferrably designed as a removable or replaceable mounting or support. Preferrably, these mountings or supports can be subjected to vacuum, and preferrably the supports are formed as a so-called substrate chuck.

The substrate is thus advantageously made safe against slipping.

Embodiments of a device hold the substrate rigidly in place during contact with the mounting. Preferrably, the apparatus for processing comprises a mounting in the form of a carrier arm with a media carrier, preferably fork-shaped, which is arranged so as to bring the substrate into a processing position.

Embodiments of an apparatus for processing a substrate are preferably suitable for bonding a component to a substrate.

The chamber upper wall of the process chamber comprises a hold-down opening for receiving at least one actuator element of the hold-down device. The actuator member is arranged such that, in use, it exerts a hold-down force received directly from outside the process chamber onto at least a portion of the substrate (300), thereby additionally keeping the substrate safe against slipping.

Preferrably, a portion of the chamber upper wall is arranged so that it can be opened to provide access to at least a portion of the interior of the process chamber.

By providing a hold-down opening in the wall of a process chamber of an apparatus for processing of a substrate and an actuator member extending from the outside of the processing chamber to the hold-down device, the technical advantage is achieved, for example, that the hold-down force exerted in the apparatus is independently predefined and/or precisely regulated in comparison to other mechanical forces in the apparatus.

Preferrably, this can also provide a high degree of thermal insulation for temperature-sensitive parts, such as an actuator drive.

Preferrably, a portion of the chamber upper wall is arranged so that it can be opened to provide access to at least a portion of the interior of the process chamber. If at least a portion of the chamber wall is arranged, for example, as a lid or hatch that can be opened to provide physical access to the process environment, the hold-down force is, to a large extent, independent of the force required to close this lid.

The part of the chamber wall that can be opened is preferrably arranged so that it can be opened without human intervention and/or automatically.

The possibility of exerting higher forces on a substrate is advantageous for holding larger and heavier substrates in place, such as those used in high-performance applications and electromobility applications. Such larger and heavier substrates are impractical in conventional hold-down devices because applying higher forces would also cause the resulting force to be directed against the lid in the opposite direction to the closing direction. Additionally, if at least a portion of the chamber wall is arranged as a lid, the lid is opened without removing parts of the hold-down device.

Embodiments of an apparatus comprise one or more process heads that are functionally arranged similarly to a gripper, wherein the one or more process heads are arranged to move positively and negatively along the third axis, and wherein process openings are arranged to accommodate one or more process heads.

Embodiments of an apparatus comprise a process head for dispensing solder onto a substrate for a soldering process.

This has the advantage that the process head is functionally similar to a solder dispenser for dispensing solder onto components for a soldering process.

Embodiments of an apparatus comprise a process head for the forming of solder on a substrate for a soldering process.

Embodiments of an apparatus further comprising a process head for releasably attaching a component, arranged such that it can be positioned with the component at the first processing position.

Embodiments of an apparatus further comprising a process head for inspection of the substrate, inspection of the component, inspection of the mounting or support, inspection after a previously accomplished process step, and/or inspection before a subsequent process step

In embodiments of an apparatus, the chamber upper wall comprises a process opening for capturing one of the process heads, several process heads, or all process heads, wherein the process opening is arranged to be suitable for at least one process head, wherein the process opening is arranged to allow for movement of at least one process head to and/or from the first processing position along a third axis, wherein the third axis is perpendicular to the first axis and perpendicular to the second axis.

In embodiments of an apparatus, the process opening and the hold-down opening are each separate openings in the chamber upper wall.

In the case of embodiments of an apparatus, the hold-down device comprises one or more hold-down projections attached to the actuator element, wherein the one or more hold-down projections are arranged to exert, in use, a hold-down force received from the actuator element directly onto at least a portion of the substrate.

In embodiments of an apparatus, the hold-down device comprises a hold-down drive arranged outside the process chamber to exert a hold-down force on the actuator element.

By providing the hold-down drive outside the processing chamber, a high degree of thermal insulation is provided between the hold-down drive and the processing chamber, and the hold-down device is arranged to exert a hold-down force on at least a portion of the further substrate along the third axis at a second processing position during use, wherein the further hold-down force is applied in use directly from outside the process chamber to at least a portion of the one or more further substrates using the actuator element.

In embodiments of an apparatus, the hold-down device comprises a hold-down member extending outside the process chamber along the second axis and arranged to exert a hold-down force on the actuator member. Preferrably, a first end portion of the hold-down member comprises a drive attachment for attachment to a hold-down drive positioned outside the process chamber; wherein a second end portion of the hold-down member comprises a pivot point arranged to convert, in use, at least a portion of the moving of the hold-down member due to operation of the hold-down drive into a degree of rotation about the first axis; and wherein the fixing of the hold-down member to the actuator member is arranged to convert, in use, at least a portion of the degree of rotation about the first axis into a degree of movement of the actuator member along the third axis toward the substrate at the first processing position, thereby exerting a hold-down force on the actuator member.

In embodiments of an apparatus, the processing chamber is arranged to provide in use, one or more processing environments. Preferrably, the processing port is arranged thereby to provide one or more gas curtains which, during use, allow for a predetermined and/or controlled flow of gas into and/or out of one or more processing environments. Preferrably, the hold-down opening is arranged to provide one or more gas curtains that, during use, allow for a predetermined and/or controlled gas flow into and/or out of one or more processing environments.

In embodiments of an apparatus, the processing chamber comprises a lower chamber wall extending along the first axis and along the second axis. Preferrably, the lower chamber wall and the support are integrally formed or fixed to each other in a form-fitting and force-fitting manner.

In the case of embodiments of an apparatus, the apparatus comprises one or more heaters and/or one or more heating elements arranged to raise the temperature of at least a portion of one or more surfaces of the substrate to be processed.

Preferrably, the one or more heaters and/or the one or more heating elements are attached to the process head. Preferably, the one or more heaters or the one or more heating elements are housed in the processing chamber or attached to the processing chamber.

In embodiments of an apparatus, the processing chamber is arranged to receive a component, and the substrate is arranged in use to receive and hold the component during processing.

In embodiments of an apparatus, a component is a semiconductor wafer, a semiconductor package, a chip, an integrated circuit, a substrate, or any combination thereof.

In embodiments of an apparatus, the apparatus comprises a media carrier arranged to move along a first axis to position the substrate at the first processing position. Preferably, the media carrier and the support are are connected integrally or in a form-and force-fitting manner to each other.

For embodiments of an apparatus that comprises a media carrier, preferrably integrally connected to a support or connected to it by form and force, comprising that is arranged such that it moves along a first axis to position the substrate at the first processing position, the media carrier is preferrably arranged to move the substrate along the first axis and to position the substrate at one or more further positions for loading the substrate, dispensing solder onto at least a portion of the processing position of the substrate, distributing solder onto at least a portion of the processing position of the substrate, processing the substrate, and/or unloading the substrate.

For embodiments of an apparatus that that a media carrier, preferrably integrally connected to a support or connected to it by form and force, comprising that is arranged to move along a first axis to position the substrate at the first processing position, the media carrier is preferrably arranged to move the substrate along the first axis and to position the substrate at one or more further positions for loading the substrate, dispensing solder onto at least a portion of the processing position of the substrate, distributing solder onto at least a portion of the processing position of the substrate, processing the substrate, and/or unloading the substrate, wherein the apparatus preferrably comprises a further process head for detachable fixing to a further component, which is arranged so that it can be positioned with the further component in a second processing position, wherein the media carrier is arranged so that it is movable along a first axis and/or along a second axis in order to position a further substrate at the second processing position.

For embodiments of an apparatus that comprises a media carrier, preferrably integrally connected to a support or connected to it by form and force, comprising a media carrier that is arranged to move along a first axis in order to position the substrate at the first processing position, the media carrier is preferrably arranged to move the substrate along the first axis and to position the substrate at one or more further positions for loading the substrate, dispensing solder onto at least a portion of the processing position of the substrate, distributing solder onto at least a portion of the processing position of the substrate, processing the substrate, and/or unloading the substrate.

For embodiments of an apparatus that comprise a media carrier, preferably integrally connected to a support or connected to it in a form- and force-fitting manner, which is arranged so that it moves along a first axis in order to position the substrate at the first processing position, the media carrier is preferrably arranged so that to move the substrate along a first axis and to position the substrate at one or more further positions for loading the substrate, dispensing solder onto at least a portion of the processing position of the substrate, distributing solder onto at least a portion of the processing position of the substrate, processing the substrate, and/or unloading the substrate. Such embodiments of an apparatus preferably also comprise a further process head for detachable fixing to a further component, which is arranged so that it can be positioned with the further component in a second processing position, wherein the media carrier is arranged so that it is movable along a first axis and/or along a second axis to position a further substrate at a second processing position.

### DESCRIPTION OF FIGURES

Advantages and characteristics of the invention result from the following figures, namely:

FIGS. 1A and 1B depict cross-sections through a part of an apparatus suitable for processing,

FIGS. 2A and 2B depict cross-sections through a part of an apparatus suitable for processing,

FIGS. 3A and 3B depict cross-sections through a part of an apparatus suitable for processing,

FIG. 4 depicts a perspective view of a hold-down device,

FIG. 5 depicts a perspective view of a part of an apparatus suitable for processing,

FIG. 6 depicts a perspective view of a part of an apparatus suitable for processing,

FIG. 7A depicts a cross-section through a part of an apparatus suitable for processing when a hold-down device is not exerting a hold-down force on a substrate,

FIG. 7B depicts a cross-section through a part of an apparatus suitable for processing when a hold-down device is exerting a hold-down force on a substrate, and

FIG. 8 depicts a cross-section through a part of an apparatus suitable for processing when a lid portion of the chamber upper wall is arranged as a lid or a hatch and is opened for access to the processing environment.

### DETAILED DESCRIPTION OF THE INVENTION

In the figures, a first axis 910, a second axis 920 and a third 930 axis are depicted. The first axis 910 is substantially perpendicular to the second axis 920, and the third axis 930 is substantially perpendicular to both the first axis 910 and the second axis 920.

It is convenient to consider the first axis 910 to be in an X direction, the second axis 920 in a Y direction and the third axis 930 in a Z direction.

In use, the first axis 910 and second axis 920 are substantially horizontal, and, in use, the third axis 930 is substantially vertical. To clarify the description of the different components, the figures depict parts in these conventional orientations. In addition, some relative terms have similarly been used, such as upper, lower, side and base to match this convention. However, the apparatus described in this disclosure may arranged by a skilled person to operate at different deviations from these conventional orientations and nominal co-ordinate axes.

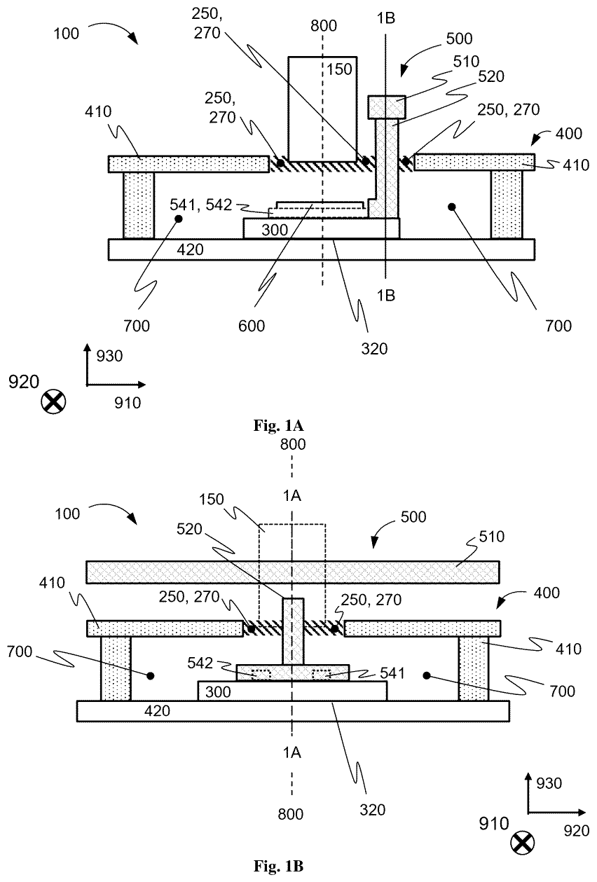

FIG. 1A and FIG. 1B are simplified and schematic cross-sections through a part of a first embodiment of a processing apparatus 100 (or first embodiment 100).

FIG. 1A depicts a longitudinal cross-sectional view lying in a plane comprising the first axis 910, nominally indicated as having a positive direction from left to right, and the third axis 930, nominally indicated as having a positive direction from bottom to top. The second axis 920 is nominally indicated as having a positive direction going into the drawing. The longitudinal cross-section passes through a first processing position 800.

FIG. 1B depicts a transverse cross-sectional view lying in the plane comprising the second axis 920, nominally indicated as having a positive direction from left to right, and the third axis 930, nominally indicated as having a positive direction from bottom to top. The first axis 910 is nominally indicated as having a positive direction going into the drawing. The longitudinal cross-section passes through the first processing position 800.

The first embodiment 100 comprises an optional process head 150 for releasably attaching to a component 600, and arranged to be positioned at the first processing position 800 with the component 600.

FIGS. 1A and 1B depict the component 600 released from the process head 150 at the first processing position 800. Prior to this depiction, the component 600 was picked up (or loaded) by the process head 150 at a pick (or load) position (not depicted), moved to the first processing position 800 and released from the process head 150. For example, the component 600 is optionally picked up from a component handling system, such as a wafer or tape. Similarly, prior to this operation, the substrate 300 may have optionally been moved to the first processing position 800 using a suitable media carrier (not depicted).

FIG. 1A and FIG. 1B depict the first embodiment 100 during processing at the first processing position 800. FIG. 1A is a simplified and schematic cross-section through a part of the first embodiment 100 at the first processing position 800 as indicated by the line 1A-1A shown in FIG. 1B. FIG. 1B is a simplified and schematic cross-section through a part of the first embodiment 100 at the first processing position 800 as indicated by the line 1B-1B shown in FIG. 1A. as depicted, the component 600 is in contact with the substrate 300, allowing one or more processing operations to be performed on at a least a portion of the one or more processing surfaces (not depicted) of the substrate 300. The process head 150 may move positively and negatively along the third axis 930, respectively away from or towards the substrate 300. Optionally, the process head 150 is arranged to rotate (not depicted) around the third axis 930.

The first embodiment 100 comprises a processing chamber 400 suitable for processing, arranged to receive the component 600. The processing chamber 400 comprises a chamber upper wall 410, extending along the first axis 910 and second 920 axis, and a chamber lower wall 420 extending along the first axis 910 and extending along second 920 axis. Optionally, the processing chamber 400 is arranged to reduce a degree of oxidation of at least a portion of the substrate 300. Optionally, the processing chamber 400 is arranged to reduce an amount of an oxide on a processing surface of the substrate 300 by flooding the processing chamber with an inert gas. Optionally, the first embodiment 100 comprises one or more processing gas inlets (not depicted) for introducing, in use, an inert gas (not depicted) to an environment 700 suitable for processing (or processing environment 700) in the interior of the processing chamber 400, wherein the processing environment 700 is predetermined and/or controlled to be suitable for the type of processing to be performed. The inert gas is any suitable inert gas, such as nitrogen, carbon dioxide, helium, neon, argon, krypton, or any combination thereof. The one or more inert gasses is optionally mixed with one or more less-inert gasses. A typical combination has the ratio of 5% hydrogen with 95% nitrogen or the ratio of 10% hydrogen with 90% nitrogen. Optionally, the first embodiment 100 is arranged to displace oxygen from the processing environment 700, thereby creating a relatively low-oxygen processing environment for processing with a relatively low inert gas consumption. This is particularly advantageous if processing includes one or more thermocompression (or TC) steps.

As depicted in FIG. 1A and FIG. 1B, the chamber upper wall 410 comprises a process opening 250, arranged to receive the process head 150 during movement of the process head 150 along the third axis 930 towards the substrate 300 at the first processing position 800. In general, the process opening 250 is dimensioned to be larger than the outer dimensions of the process head 150. Optionally, if the process head is arranged functionally similar to a gripper and if the outer dimensions of the component 600 are larger than the outer dimensions of the process head 150, the process opening 250 is dimensioned to be larger than the outer dimensions of the component 600. Optionally, the process opening 250 is arranged to provide one or more gas curtains allowing a predetermined and/or controlled flow of inert gas out of the processing environment 700. In the example depicted in FIG. 1A and FIG. 1B, the process opening 250 extends around the periphery of the process head 150. Optionally, it may also be advantageous to reduce the average separation of at least a portion of the process opening 250 by attaching a sealing lip to the chamber upper wall 410 and/or to the process head 150. Optionally, it is advantageous if the dimensions of the processing environments and any openings are predetermined and/or controlled to provide a relatively small volume for the required processing environment to reduce gas consumption. Optionally, a portion of the chamber upper wall is arranged to be openable to provide access to at least a portion of the interior of the processing chamber. Optionally, the process opening 250 is covered by a process opening lid that is connected to the process head 150 and moves with the process head along the first axis 910 and/or along the second axis 920. The lid is designed to cover at least part of the process opening 250.

The first embodiment 100 comprises a hold-down device 500 (or first variant 500 of a hold-down device), arranged to exert in use, a hold-down force on at least a portion of the substrate 300 along the third axis 930 against the support 320 at the first processing position 800. The chamber upper wall 410 comprises a hold-down opening 270 for receiving at least an actuator member 520 of the hold-down device 500, and for allowing the actuator member 520 of the hold-down device 500, in use, to directly exert the hold-down force from outside the processing chamber 400 on at least a portion of the substrate 300. In the prior art solutions, the hold-down force creates a counter force that acts against the chamber upper wall. However, due to the arrangement of the apparatus 100, and in particular the arrangement of pivot points of the hold-down device 500 and chamber upper wall 410, the influence from the hold-down force to the chamber upper wall 410 is less than 10%, or less than 5%, or less than 1%. Optionally, the hold-down opening 270 is arranged to provide one or more gas curtains allowing, during use, a predetermined and/or controlled flow of the gas out of the processing environment 700.

In the example depicted in FIG. 1A and FIG. 1B, the hold-down device 500 comprises a first member 510 extending outside the processing chamber 400 along the second axis 920, arranged to directly exert the hold-down force on an actuator member 520 of the hold-down device 500. The actuator member 520 of the hold-down device 500 is optionally any element or member, which can be arranged to directly exert the hold-down force from outside the processing chamber 400 to at least a portion of the substrate 300. The actuator member 520 of the hold-down device 500 comprises one or more sub-members, rigidly attached to each other. The hold-down device 500 depicted comprises one or more hold-down protrusions 541, 542 attached to the actuator member 520 of the hold-down device 500, wherein the one or more hold-down protrusions 541, 542 are arranged to directly exert, in use, the hold-down force transferred by the actuator member 520 of the hold-down device 500 to at least a portion of the component 600. More specifically, in the example depicted, the one or more hold-down protrusions 541, 542 are two extended protrusions, each arranged to be positioned along the first axis 910 proximate an edge of the component 600.

In the non-limiting example depicted in FIG. 1A and FIG. 1B, the actuator member 520 extends along the third axis 930, and extends along the second axis 920. The actuator member 520 is attached to the one or more hold-down protrusions 541, 542 and arranged to transfer a hold-down force received by the actuator member 520 to the one or more hold-down protrusions 541, 542. In some arrangements, it is advantageous for the actuator member 520 to comprise a plurality of hold-down sub-members, rigidly attached to each other to allow an efficient transfer of force. If the optional first hold-down member 510 is provided, the first hold-down member 510 is attached to the actuator member 520, and arranged to transfer a hold-down force received by the first hold-down member 510 to the actuator member 520.

By providing a hold-down opening 270 in the chamber upper wall 410 of the processing chamber 400, and providing an actuator member 520 that extends from outside the processing chamber 400 to at least a portion of the component 600, the hold-down force exerted is independently predetermined and/or controlled to a high degree compared to other mechanical forces in the apparatus. For example, the hold-down force exerted is thereby independent to a high degree of any other forces exerted using one or more walls of the processing chamber 400. Optionally, a portion of the chamber upper wall is arranged to be openable to provide access to at least a portion of the interior of the processing chamber. For example, even if at least a portion of the chamber upper wall 410 is arranged as a lid (or hatch), arranged to be opened to gain physical access to the process environment 700, the hold-down force exerted through the actuator member 520 is independent to a high degree of the force required to close this lid. In other words, the hold-down device 500 is mechanically isolated to a high degree by providing one or more gaps between the walls of the hold-down opening 270 and the portion of the actuator member 520 passing through the hold-down opening 270. For example, the hold-down force exerted on the substrate 300 is up to 75 newtons (N) at the first processing position 800. Allowing higher forces to be exerted is advantageous for rigidly retaining larger and heavier components such as those currently being used for high power applications and electro-mobility applications. These larger and heavier substrates are inconvenient in conventional hold-down devices because arranging higher forces would also cause the resulting force to also act on the lid against the closing direction.

Additionally or alternatively, a high degree of thermal isolation is provided. For example, temperature-sensitive parts of the hold-down device 500, such as drives, are positioned outside the processing environment 700, which may allow such temperature-sensitive parts to be thermally isolated to a high degree, particularly if the processing chamber is heated to temperature between 250 and 500 degrees Celsius determined by the materials to be processed. Preferably, a high degree of thermal isolation is provided using one or more air gaps between the walls of the processing chamber 400 and the temperature-sensitive parts.

Preferably, a portion of the chamber upper wall is arranged to be openable to provide access to at least a portion of the interior of the processing chamber. If at least a portion of the chamber upper wall 410 is arranged as a lid to be opened for physical access, it is advantageous to arrange the parts of the hold-down device 500 outside the processing chamber 400 to be easily removable, or to be easily movable out of the way of any lid.

Preferably, the first embodiment 100 comprises one or more heaters and/or one or more heating elements (both not depicted) arranged such that, in use, they warm or heat for processing at least a portion of one or more surfaces of a substrate 300 to be processed. Preferably, the one or more heaters or the one or more heating elements are comprised in the process head 150. Additionally or alternatively, the one or more heaters and/or one or more heating elements are comprised in the processing chamber (400). The one or more heater and/or one or more heating elements may provide heat to the one or more processable surfaces using conduction, convection, radiation or any combination thereof. Use of one or more heaters are advantageous if the first embodiment 100 is used in a processing process which includes one or more heating operations, such as a thermocompression (TC) operation. For example, it is required to heat at least a portion of one or more processing surfaces up to temperatures between 250 and 500 degrees Celsius determined by the materials to be processed. To achieve that, one or more heaters and/or one or more heating elements are provided, which are comprised in the process head 150, having a heating capacity to 500 degrees Celsius or higher. Alternatively or additionally, one or more heater and/or one or more heating elements are comprised in the chamber lower wall 420 with a heating capacity up to 550 to 600 degrees Celsius.

Preferably, it is also advantageous to create and/or maintain any required processing environment during a heating of the one or more component processing surfaces. Preferably, the first embodiment 100 is arranged to exert, in use, a bonding pressure to at least a portion of one or more processing surfaces of the substrate 300. For example, a bonding force of up to 500 N (newton) is applied to exert such a bonding pressure.

As depicted in FIG. 1A and FIG. 1B, the process opening 250 and the hold-down opening 270 may optionally at least partially overlap. In other words, the process opening 250 and the hold-down opening 270 are contiguous (or combined) openings in the chamber upper wall 410.

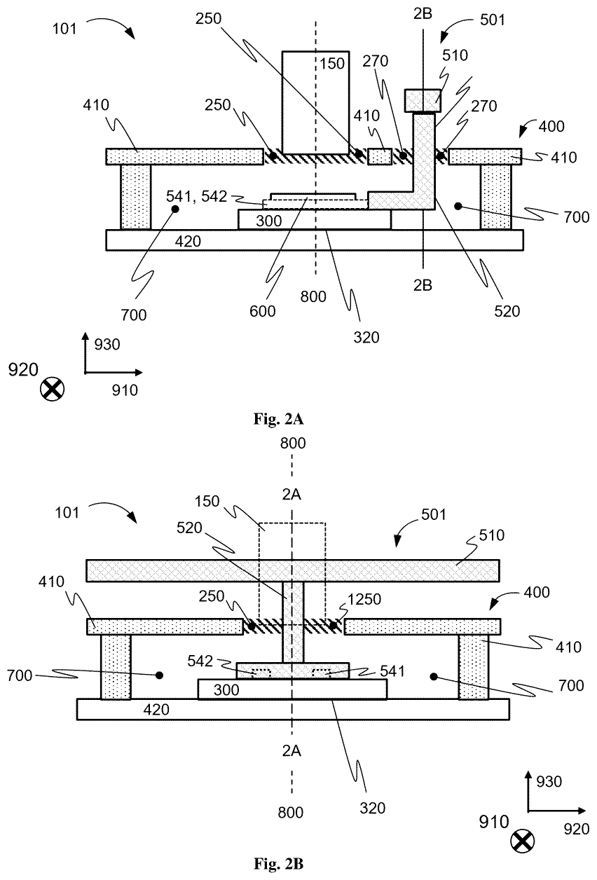

FIGS. 2A and 2B are simplified and schematic cross-sections through a part of a second embodiment of a processing apparatus 101 (or second embodiment 101). The second embodiment 101 comprises the same functions as described above for the first embodiment 100, and may similarly comprise the optional functions and optional features described above. The second embodiment 101 comprises the same features as described above for the first embodiment 100, except for the following differences A01 to A03:
A01: The process opening 250 and the hold-down opening 270 are separate openings in the chamber upper wall 410. In the example depicted in FIG. 2A and FIG. 2B, the process opening 250 and the hold-down opening 270 are separated along the first axis 910. Additionally or alternatively, the process opening 250 and the hold-down opening 270 are separated along the second axis 920.
A02: The second embodiment 101 comprises a second variant 501 of a hold-down device 501 (or second variant 501). The second variant 501 is the same as the first variant 500, except for the actuator member 520 extending substantially further along the first axis 910 in the negative direction to allow the hold-down force received from the first hold-down member 510 to be transferred to the one or more hold-down protrusions 541, 542. This is advantageous for thermal isolation because it may reduce the number and size of openings in the chamber upper wall 410 positioned directly above the first processing position 800.
A03: FIG. 2A is a simplified and schematic cross-section through a part of the second embodiment 101 at the first processing position 800 as indicated by the line 2A-2A shown in FIG. 2B. FIG. 2B is a simplified and schematic cross-section through a part of the second embodiment 101 at the first processing position 800 as indicated by the line 2B-2B shown in FIG. 2A.

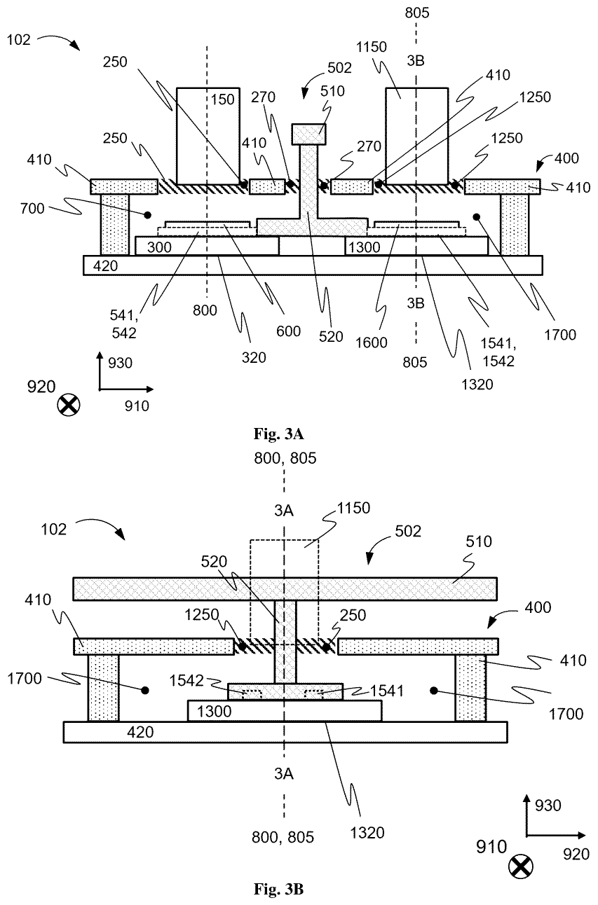

FIG. 3A and FIG. 3B are simplified and schematic cross-sections through a part of a third embodiment of a processing apparatus 102 (or third embodiment 102). The third embodiment 102 comprises the same functions as described above for the first embodiment 100 and second embodiment 101, and may similarly comprise the optional functions and optional features described above. The third embodiment 101 comprises the same features as described above for the second embodiment 102, except for the following differences B01 to B07:
B01: The third embodiment 102 comprises a second processing position 805. In the example depicted, the second processing position 805 is separated along the first axis 910 from the first processing position 800, and the functions and features provided at the second processing position 805 are analogous to the functions and features provided at the first processing position 800. Additionally or alternatively, the first processing position 800 and the second processing position 805 are separated along the second axis 920. The processing provided at the second processing position 805 are identical, the same, similar, or different to the processing provided at the first processing position 800.
B02: In the example depicted, the third embodiment 102 processing comprises a further process head 1150. The functions and features provided with the further process head 1150 are analogous to the functions and features provided with the process head 150. Additionally or alternatively, the third embodiment 102 are arranged to move the process head 150 between the first processing position 800 and the second processing position 805, allowing the same process head 150 to be used in one or more processing positions 800, 805.
B03: In the example depicted, the second processing position 805 is arranged for processing a further substrate 1300 while being rigidly retained against a further support 1320. Additionally or alternatively, the second processing position 805 are arranged to process the further component 1600 as a parallel process to the processing performed at the first processing position 800.
B04: The third embodiment 102 comprises a further process opening 1250 in the chamber wall 410, which is separate from the process opening 250 and separate from the hold-down opening 270. In the example depicted, the further process opening 1250 and the process opening 250 are separated along the first axis 910. Additionally or alternatively, the further process opening 1250 and the process opening 250 are separated along the second axis 920.
B05: The third embodiment 102 comprises a third variant of a hold-down device 502 (or third variant 502). It is the same as the second variant 501, except for the actuator member 520 extending substantially further along the first axis 910 in the positive direction to allow the hold-down force received from the first hold-down member 510 to be transferred to one or more further hold-down protrusions 1541, 1542 provided in the second processing position 805. The third variant 502 is the same as the second variant 501 in respect of the actuator member 520 extending substantially along the first axis 910 in the negative direction to allow the hold-down force received from the first hold-down member 510 to also be transferred to one or more hold-down protrusions 541, 542 provided in the first processing position 800. For example, the hold-down force exerted on the substrate 300, 1600 is up to 75 newtons (N) at each processing position 800,805.
B06: A further processing environment 1700 is provided at the second processing position 805 in the interior of the processing chamber 400 between the further substrate 1300 and the further process head 1150. The further processing environment 1700 is predetermined and/or controlled to be suitable for processing. Optionally, a further processing environment 1700 is provided which is identical, same, similar or different to the processing environment 700 at the first processing position 800.
B07: FIG. 3A is a simplified and schematic cross-section through a part of the third embodiment 102 at the first processing position 800 and the second processing position 805 as indicated by the line 3A-3A shown in FIG. 3B. FIG. 3B is a simplified and schematic cross-section through a part of the third embodiment 102 at the second processing position 805 as indicated by the line 3B-3B shown in FIG. 3A.

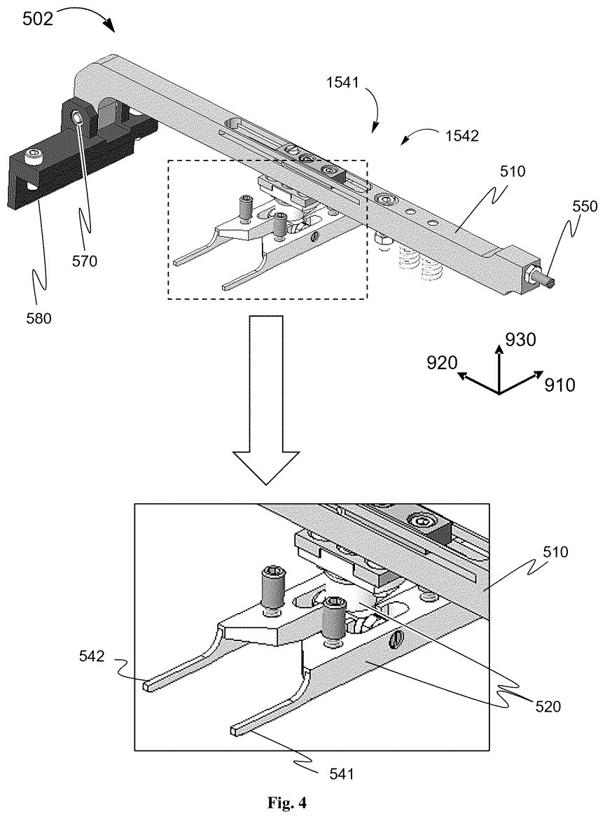

FIG. 4 depicts a perspective view of the third variant 502, and an enlarged perspective view of the actuator member 520 and the hold-down protrusions 541, 542. In this non-limiting example, the actuator member 520 extends along the third axis 930 in the negative direction, and extends along the second axis 920 in both the positive direction and the negative direction.

The third variant 502 comprises the first hold-down member 510, extending along the second axis 920, arranged to directly exert the hold-down force to the actuator member 520. The first hold-down member 510 is arranged to be extended outside the processing chamber (not depicted in FIG. 4). The following aspects, C01 to C04, are depicted in FIG. 4 and are not depicted, or not fully depicted, in FIG. 3A or FIG. 3B:
C01: In the example depicted, more details are shown of the arrangement of the first hold-down member 510. The first hold-down member 510 comprises a first end portion with a drive attachment 550 for attachment to a hold-down drive (not depicted). The first hold-down member 510 comprises a second end portion comprising a pivot point 570, arranged to convert, in use, at least a portion of movement of the first hold-down member 510 due to the operation of the hold-down drive 560 to a degree of rotation about the first axis 910.
C02: In the example depicted, more details are shown of the arrangement of the actuator member 520. The attachment of the first hold-down member 510 to the actuator member 520 is arranged to convert, in use, at least a portion of the degree of rotation about the first axis 910 to a degree of movement of the actuator member 520 along the third axis 930 towards the support (not depicted) at the first processing position 800, thereby transferring a hold-down force received by the hold-down member 510 to the actuator member 520.
C03: In the example depicted, more details are depicted of a possible arrangement of hold-down protrusions 541, 542 attached to the actuator member 520, which are two extended finger-like hold-down protrusions 541, 542, each extending along the first axis 910 in the negative direction, and to be positioned proximate an edge of the component (not depicted).
C04: In the example, the third embodiment 502 also comprises further hold-down protrusions 1541, 1542 attached to the actuator member 520. These hold-down protrusions 1541, 1542 are not shown in the view shown in FIG. 4 because they are hidden behind the first member 510. The further hold-down protrusions 1541, 1542 are similar to the hold-down protrusions 541, 542 because they are two extended finger-like protrusions, each extending along the first axis 910 in the positive direction, and each arranged to be positioned proximate an edge of the component (not depicted).

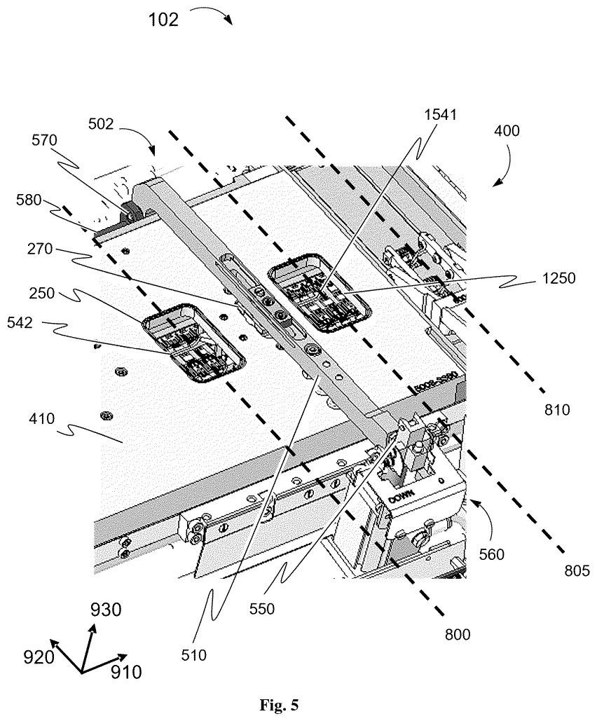

FIG. 5 depicts a further perspective view of part of the processing chamber comprised in the third embodiment 102 of a bonding apparatus (or third embodiment 102). The third embodiment 102 comprises the third variant of a hold-down device 502 (or third variant 502) described above in relation to FIG. 4. However, FIG. 5 shows the third variant 502 after assembly, and after the processing chamber 400 has been closed. In other words, the third embodiment 102 is shown ready for use for processing. The following aspects, D01 to D09, are depicted in FIG. 5 and are not depicted, or not fully depicted, in FIG. 3A or FIG. 3B:
D01: The third embodiment 102 comprises a hold-down drive 560, arranged to be positioned outside the processing chamber 400. The hold-down drive 560 is connected to the drive attachment 550 of the first hold-down member 510, allowing the hold-down drive 560 to exert a hold-down force on the first end portion of the first hold-down member 510, whereby, in use, a degree of rotation is provided about the first axis 910, and specifically a degree of rotation about the pivot point 570 comprised in the second end portion of the first hold-down member 510.
D02: In the example depicted, the first hold-down member 510 extends outside the processing chamber 400 along the second axis 920, and is arranged to exert the hold-down force to the actuator member (not depicted). The actuator member is not depicted in FIG. 5 because it is hidden behind the chamber upper wall 410, and behind the first hold-down member 510. The first end portion of the first hold-down member 510 comprises a drive attachment 550, which is shown as attached to the hold-down drive 560, whereby the third embodiment 102 is ready for use for component processing. The second end portion of the first hold-down member 510 comprises the pivot point 570, which is attached to the third embodiment 102 such that in use, at least a portion of movement of the first hold-down member 510, due to the operation of the hold-down drive 560, is converted to a degree of rotation about the first axis 910.
D03: The first hold-down member 510 extends between the pivot point 570 and the drive attachment 550 along the outer surface of the upper chamber wall 410. The first hold-down member 510 is positioned over the hold-down opening 270, and is attached to the actuator member (not depicted), and arranged to transfer the hold-down force received by the first hold-down member 510 to the actuator member (not depicted) through the hold-down opening 270. In the example depicted in FIG. 5, the hold-down opening 270 is separate from the process opening 250 and also separate from the further process opening 1250.
D04: The process head and further process head are not depicted in FIG. 5. The chamber upper wall 410 comprises the process opening 250, arranged to receive the process head (not depicted) during movement of the process head (not depicted) along the third axis 930 towards the support (not depicted). Similarly, the chamber upper wall 410 comprises a separate further process opening 1250, arranged to receive the further process head (not depicted) during movement of the further process head (not depicted) along the third axis 930 towards the further support (not depicted). Additionally or alternatively, as described above, the further process opening 1250 is arranged to receive the process head (not depicted). In the example depicted in FIG. 5, the openings 250, 270, 1250 in the chamber upper wall 410 are depicted as approximately rectangular in cross-section. However, any convenient cross-sectional shape is used.
D05: One of the hold-down protrusions 542 is depicted in FIG. 5 because it is visible in this view through the process opening 250. A second hold-down protrusion is hidden in this perspective view. Similarly, one of the further hold-down protrusions 1541 is depicted in FIG. 5 because it is visible in this view through the further process opening 1250. A second further hold-down protrusion is hidden in this perspective view.
D06: The pivot point 570 is rigidly attached such that, in use, at least a portion of movement of the first hold-down member 510 is converted to a degree of rotation about the first axis 910. Optionally, as depicted in the example of FIG. 5, the mechanical attachment 580 of the pivot point 570 is rigidly attached to an outside surface of the processing chamber 400. Optionally, as depicted in the example of FIG. 5, the mechanical attachment 580 is rigidly attached to a suitable portion of the chamber lower wall 420. Optionally, it is advantageous to rigidly attach the pivot point 570 to a part which is mechanically isolated to a high degree from the processing chamber 400—this may increase a degree of mechanical isolation of the third variant 502 of a hold-down device from the processing chamber 400. Optionally, a high degree of mechanical isolation is provided using one or more gaps between the processing chamber 400 and the part to which the pivot point 570 is rigidly attached.
D07: The hold-down drive 560 is rigidly attached such that, in use, a hold-down force is exerted on the first end portion of the first hold-down member 510. Optionally, the hold-down drive 560 is rigidly attached to an outside surface of the processing chamber 400. Optionally, the hold-down drive 560 is rigidly attached to a suitable portion of the chamber upper wall 410. Optionally, as depicted in the example of FIG. 5, the hold-down drive 560 is rigidly attached to a part which is mechanically isolated to a high degree from the processing chamber 400—this may increase a degree of mechanical isolation of the third variant 502 of a hold-down device from the processing chamber 400. Additionally or alternatively, this may increase a degree of thermal Isolation of the third variant 502 from the processing chamber 400. Optionally, a high degree of thermal and/or mechanical isolation is provided using one or more gaps between the walls of the processing chamber 400 and the temperature-sensitive hold-down drive 560. The hold-down drive 560 may generate and provide the hold-down force using any suitable means, such as mechanical, electrical, magnetic, induction, pneumatic, hydraulic or any combination thereof.
D08: The third embodiment 102 comprises an optional further processing position 810. In the example depicted, the further processing position 810 is separated along the first axis 910 from the first processing position 800, and also separated along the first axis 910 from the second processing position 805. Additionally or alternatively, the further processing position 800 and the second processing position 805 are separated along the second axis 920. In the example depicted, the processing chamber 400 does not extend to the further processing position, so the functions and features provided at the further processing position 805 are different to the functions and features provided at the first processing position 800, and also different to functions and features provided at the second processing position 810. The processing provided at the further processing position 810 is similar or different to the processing provided at the second processing position 805, and also similar or different to the processing provided at the first processing position 800. In the example depicted, the second processing position 805 is positioned between the first processing position 800 and the further processing position 810. For example, a solder dispensing process is provided at the first processing position 800, a solder pre-press process is provided at the second processing position 805, and a bond process provided at the further processing position 810, wherein the third variant 502 of a hold-down device is arranged to rigidly retain a component (not depicted) during solder dispensing and solder pre-press, and wherein the third embodiment 102 of a processing apparatus is arranged to move the component with applied solder to the further processing position 810 for bonding.
D09: optionally, a component drive (not depicted) is provided at least partially inside the processing chamber 400 to provide for movement of one or more components between separate processing positions. For example, a media carrier or substrate handler is provided for moving the one or more components. For example, one or more components are moved using an index pin (not depicted), wherein the index pin is arranged to be received by corresponding holes in the one or more components such that the one or more components are moved through the processing chamber between processing positions 800, 805, 810.

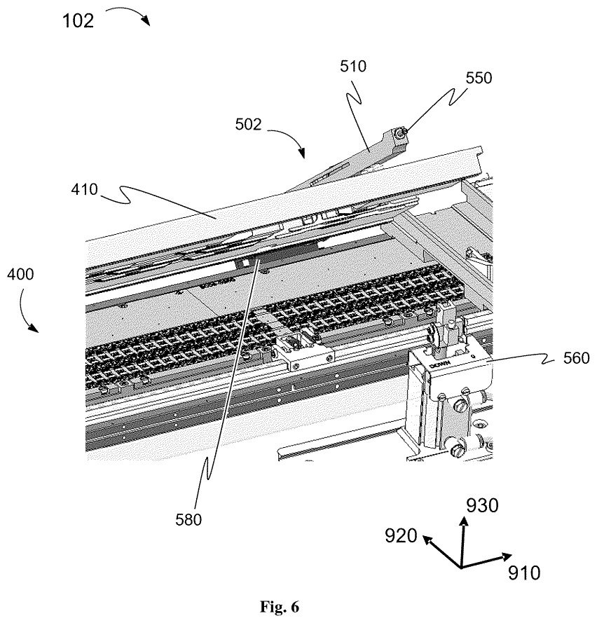

FIG. 6 depicts a further perspective view of part of the processing chamber comprised in the third embodiment 102 of a bonding apparatus (or third embodiment 102). The third embodiment 102 comprises the third variant of a hold-down device 502 (or third variant 502) described above in relation to FIG. 4. However, FIG. 6 shows the third variant 502 during assembly or maintenance, and before closing the processing chamber 400 for use, wherein a portion of the chamber upper wall 410 has been optionally arranged to open as a lid for access to the inside of the processing chamber 400. In other words, the third embodiment 102 is shown when the third embodiment 102 is not being used for processing. For example, opening of the lid portion of the chamber upper wall 410 may provide physical access to the processing environment, to the support, to the component or to a module or device included in the processing chamber 400. The following aspects, E01 to E03, are depicted in FIG. 6 and are not depicted, or not fully depicted, in FIG. 3A or FIG. 3B:
E01: In the example depicted, the hold-down drive 560 and the drive attachment 550 of the first hold-down member 510 have been detached from each other, allowing the first hold-down member 510 to rotate around the first axis 910 at the pivot point (not depicted). Optionally, as depicted in the example of FIG. 6, the mechanical attachment 580 of the pivot point (not depicted) is rigidly attached to a suitable portion of the chamber lower wall 420, allowing the first hold-down member 510 to rotate around the first axis 910 with the lid portion of the chamber upper wall 410. Optionally, the hold-down drive 560 and/or the drive attachment 550 is arranged to allow quick detachment and/or quick attachment.
E02: In the example depicted, the hold-down drive 560 is rigidly attached to a part which is mechanically isolated to a high degree from the processing chamber 400. Optionally, a high degree of mechanical isolation is provided using one or more gaps between the processing chamber 400 and the part to which the hold-down drive 560 is rigidly attached. In the example depicted, the hold-down drive 560 is not rigidly attached to the upper chamber wall 410, allowing the lid portion of the chamber upper wall 410 to be rotated around the first axis 910.
E03: Optionally, the lid portion of the chamber upper wall 410 comprises one or more hinges (not depicted), arranged to allow a degree of rotation around the first axis 910 for opening and closing. Optionally, it is advantageous to position the pivot point (not depicted) on approximately the same rotation axis as the one or more hinges (not depicted).

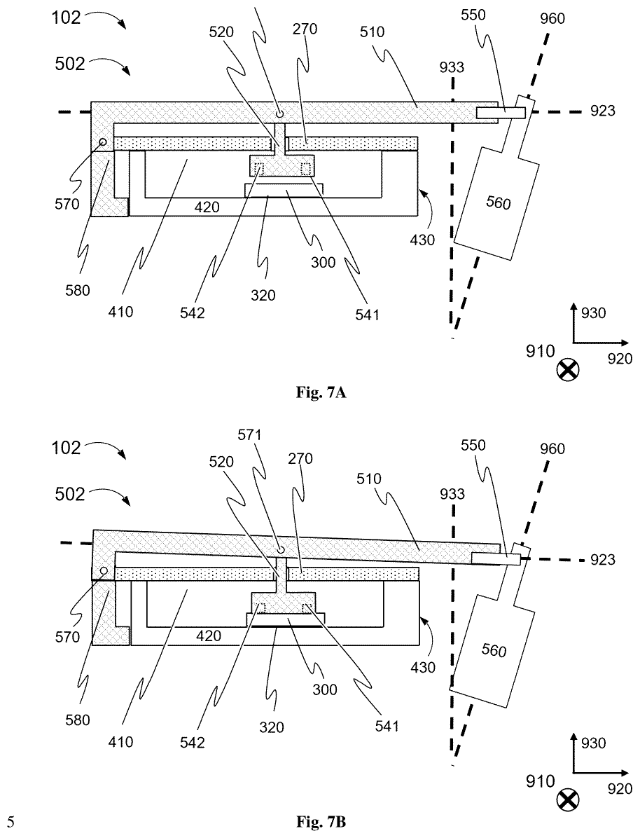

FIG. 7A and FIG. 7B are simplified and schematic cross-sections through a part of the processing chamber comprised in the third embodiment of a bonding apparatus 102 (or third embodiment 102). The third embodiment 102 comprises the third variant of a hold-down device 502 (or third variant 502) described above in relation to FIG. 4. However, FIG. 7A and FIG. 7B show the third variant 502 after assembly, and after the processing chamber has been closed. The third embodiment 102 is shown during two moments during use for processing—FIG. 7A shows the third variant 502 not exerting a hold-down force on the substrate 300, and FIG. 7B shows the third variant 502 exerting a hold-down force on the substrate 300. The following aspects, F01 to F07, are depicted in FIG. 7A and FIG. 7B, and are not depicted, or not fully depicted, in FIG. 3A or FIG. 3B:
F01: The third embodiment 102 comprises the hold-down drive 560, positioned outside the processing chamber. The hold-down drive 560 is connected to the drive attachment 550 of the first hold-down member 510, allowing the hold-down drive 560 to exert a hold-down force on the first end portion of the first hold-down member 510. In the example depicted, the hold-down drive 560 is positioned to actuate along a hold-down drive axis 960 which is not parallel to the third axis 930.
F02: The first hold-down member 510 extends outside the processing chamber, and is oriented along a first hold-down member axis 923. The first hold-down member 510 is arranged to rotate about the pivot point 570 such that a hold-down force is applied to the actuator member 520.
F03: The first hold-down member 510 is attached to the actuator member 520 by means of an actuator member pivot point 571, and is arranged to transfer the hold-down force received by the first hold-down member 510 through the hold-down opening 270.
F04: In the example depicted, the actuator member 520 extends substantially further along the first axis 910 in the negative direction to allow the hold-down force received from the first hold-down member 510 to be transferred to the one or more hold-down protrusions 541, 542. In the example depicted, the one or more hold-down protrusions 541, 542 are two extended protrusions, extending along the first axis 910. In FIG. 7A, the first hold-down member 510 is shown in a non-exertion position, wherein the one or more hold-down protrusions 541, 542 are not exerting a substantial force on the substrate 300. In FIG. 7B, the first hold-down member 510 is shown in an exertion position, wherein the one or more hold-down protrusions 541, 542 are exerting a substantial force on the substrate 300.
F05: In the example depicted, the hold-down drive 560 is rigidly attached to an outside surface of the processing chamber. In other words, the hold-down drive 560 is not attached to a chamber front wall 430 of the processing chamber 400, wherein the gap provides a high degree of mechanical isolation of the third variant 502 from the processing chamber. Additionally or alternatively, a high degree of thermal isolation is provided by a substantial air gap between the temperature-sensitive hold-down drive 560 and the chamber front wall 430.
F06: In the example depicted, the substrate 300 has been positioned at a processing position, allowing one or more processing operations to be performed on at a least a portion of one or more processing surfaces (not depicted) of the substrate 300. The one or more hold-down protrusions 541, 542 are arranged to directly exert, in use, the hold-down force transferred by the actuator member 520 to at least a portion of the substrate 300. In the example depicted in FIG. 7B, the one or more hold-down protrusions 541, 542, each arranged to be positioned along the first axis 910 proximate an edge of the substrate 300.
F07: In FIG. 7A, the hold-down drive 560 is shown in a non-exertion position, wherein an actuator (not depicted) of the hold-down drive 560 is rigidly attached to the drive attachment 550 such that the first hold-down member axis 923 is approximately parallel to the second axis 920. In FIG. 7B, the hold-down drive 560 is shown in an exertion position, wherein an actuator (not depicted) of the hold-down drive 560 is rigidly attached to the drive attachment 550 such that the first hold-down member axis 923 is not parallel to the second axis 920. For example, the hold-down drive 560 is arranged to move a position of the actuator (not depicted) between a non-exertion position as depicted in FIG. 7A, and one or more exertion positions such as the position depicted in FIG. 7B. For example, the hold-down drive 560 is arranged to move a position of the actuator (not depicted) to one or more exertion positions such as the position depicted in FIG. 7B, and allow the actuator (not depicted) to move to a non-exertion position as depicted in FIG. 7A by releasing the force exerted by the hold-down drive 560. Additionally or alternatively, the processing chamber is provided with one or more resilient elements, such as springs (not depicted) to assist in moving or resisting the actuator (not depicted) between one or more positions. Additionally or alternatively, the processing chamber is provided with one or more buffers, such as stoppers (not depicted), to assist in resisting movement of the actuator (not depicted) or limiting a range of movement. The one or more resilient elements (not depicted) or the one or more buffers (not depicted) is advantageously positioned between chamber upper wall 410 and the first hold-down member 510.

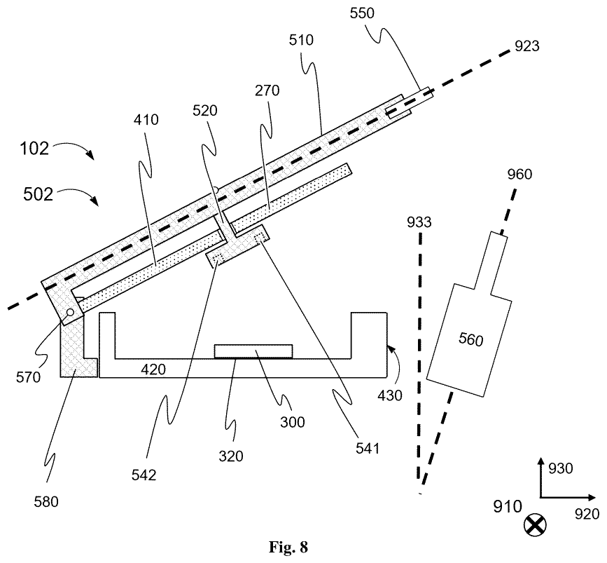

FIG. 8 is a simplified and schematic cross-section through a part of the processing chamber comprised in the third embodiment 102. The third embodiment 102 comprises the third variant of a hold-down device 502 described above in relation to FIG. 4. However, FIG. 8 shows the third variant during assembly or maintenance, and before closing the processing chamber for use, wherein a portion of the chamber upper wall 410 has been optionally arranged to open as a lid for access to the inside of the processing chamber. In other words, the third embodiment 102 is shown when the third embodiment 102 is not being used for processing. The following aspects, G01 to G04, are depicted in FIG. 8 and are not depicted, or not fully depicted, in FIG. 3A or FIG. 3B.
G01: In the example depicted, the hold-down drive 560 is positioned to actuate along the hold-down drive axis 960 which is not parallel to the third axis 930. This is advantageous in allowing opening and closing of the lid portion of the chamber upper wall 410 with a reduced actuation range of the hold-down drive. For example, the angle between the hold-down drive axis 960 and the third axis 930 is in the range 5 to 20 degrees, or in the range of 5 to 15 degrees, or approximately 10 degrees. In the example depicted, the attachment point of the actuator (not depicted) of the hold-down drive 560 is tilted away from the chamber front wall 430 by this angle.
G02: In the example depicted, the mechanical attachment 580 of the pivot point 570 is rigidly attached to a suitable portion of the chamber lower wall 420. In the example depicted, the drive attachment 550 and the actuator (not depicted) of the hold-down drive 560 have been detached from each other, allowing the first hold-down member 510 to rotate around the first axis 910 with the lid portion of the chamber upper wall 410. It is advantageous for the lid portion of the chamber upper wall 410 and the first hold-down member 510 to optionally rotate around the same pivot point 570 to reduce the complexity of the opening components.
G03: In the example, the hold-down drive 560 is shown beyond a non-exertion position where the actuator (not depicted) has detached from the drive attachment 550. Optionally, the hold-down drive 560 and/or the drive attachment 550 is arranged to allow quick detachment. For example, the actuator (not depicted) of the hold-down drive 560 is arranged to automatically detach from the drive attachment 550 if the actuator (not depicted) is moved to a non-exertion position, or if the actuator (not depicted) is moved beyond a non-exertion position. For example, a distal end of the actuator (not depicted) comprises one or more blocking pins, arranged to retain attachment to the drive attachment 550 at exertion positions. However, as the distal end of the actuator (not depicted) moves to non-exertion positions along the hold-down drive axis 930, the angle between the hold-down drive axis 960 and the third axis 930 causes the distal end of the actuator (not depicted) to also move away from the chamber front wall 430 until the first hold-down member 510 can rotate around the first axis 910 because the drive attachment 550 is no longer prevented from rotation by the one or more blocking pins (not depicted). The movement of the distal end of the actuator (not depicted) is powered by the hold-down drive 560 or the movement is performed manually by an operator.
G04: Optionally, the hold-down drive 560 and/or the drive attachment 550 is arranged to allow quick attachment by reversing the procedure described in G03. In other words, the processing chamber is closed by rotating the first hold-down member 510 with the lid portion of the chamber upper wall 410 back around the first axis 910. When the first hold-down member axis 923 is approximately parallel to the second axis 920, the distal end of the actuator (not depicted) is moved to an exertion position, whereby attachment to the drive attachment 550 by the one or more blocking pins, is retained at exertion positions. The movement of the distal end of the actuator (not depicted) is powered by the hold-down drive 560 or the movement is manually performed by an operator.

The embodiments described herein are further modifiable to provide a higher degree of throughput, a higher degree of flexibility, a higher degree of accuracy, or any combination thereof.

In summary, hold-down devices are used in processing machines to press the substrate against a support during at least a part of a heating step. However, inaccuracies are introduced due to the hold-down device and/or the hold-down drive being non-uniformly heated. An improved processing apparatus 100, 101, 102 is provided for processing a substrate comprising a hold-down device 500, 501, 502 arranged to exert, in use, a hold-down force on at least a portion of the substrate. The processing chamber 400 comprises a hold-down opening 270 for receiving an actuator member 520 of the hold-down device, wherein the hold-down force is directly exerted, in use, from outside the processing chamber 400. This allows the hold-down force exerted to be independently predetermined and/or controlled to a high degree. Additionally, this may also provide a high degree of thermal and/or mechanical isolation, improving the accuracy. This is particularly advantageous where a part of the processing chamber 400 is arranged to be openable as a lid or hatch.

### REFERENCE NUMBER LIST

100 first embodiment of an apparatus
101 second embodiment of an apparatus
102 third embodiment of an apparatus
150 process head
250 process opening
270 hold-down opening
300 substrate
320 support
400 processing chamber
410 chamber upper wall
420 lower wall
430 chamber front wall
500 first variant of a hold-down device
501 second variant of a hold-down device
502 third variant of a hold-down device
510 first hold-down member
520 actuator member
541, 542 hold-down protrusions
550 drive attachment
560 hold-down drive
570 pivot point
1571 actuator member pivot point
580 mechanical attachment for a pivot point
600 component

700 processing environment
800 first processing position
805 second processing position
810 further processing position
910 first axis (X)
920 second axis (Y)
923 first hold-down member axis
930 third axis (z)
933 chamber front wall axis
960 hold-down drive axis
1250 further process opening
1150 further process head
1300 further substrate
1320 further support
1541, 1542 further hold-down protrusions
1600 further component
1700 further processing environment

1. Apparatus (100) for processing a substrate (300), the apparatus (100, 101, 102) comprising a processing chamber (400), the processing chamber (400) comprising a chamber upper wall (410) extending along a first axis (910) and extending along a second axis (920), the second axis (920) being perpendicular to the first axis (910); and wherein the substrate (300) is arranged, in use, to be processed at a first processing position (800); and wherein the apparatus (100, 101, 102) further comprises a hold-down device (500, 501, 502), arranged to exert, in use, a hold-down force on at least a portion of the substrate (300) along a third axis (930) against a support (320) at the first processing position (800); wherein the chamber upper wall (410) comprises a hold-down opening (270) for receiving at least an actuator member (520) of the hold-down device (500, 501, 502); and wherein the actuator member (520) is arranged such that, in use, a hold-down force, which is directly received from outside the process chamber (400), is exertable on at least a portion of the substrate (300).

2. Apparatus according to claim 1, wherein a portion of the chamber upper wall (410) is arranged to be openable to provide access to at least a portion of the interior of the processing chamber (400).

3. Apparatus according to claim 1, wherein the apparatus further comprises a process head (150) for dispensing solder onto a substrate (300) for a solder process.

4. Apparatus according to claim 1, wherein the apparatus further comprises a process head (150) for shaping solder on a substrate (300) for a solder process.

5. Apparatus according to claim 1, wherein the apparatus further comprises a process head (150) for releasably attaching to a component (600), arranged to be positioned at the first processing position (800) with the component (600).

6. Apparatus according to claim 1, wherein the apparatus further comprises a process head (150) for inspection of the substrate (300), inspection of a component (600), inspection of the support (320), inspection after an earlier processing step, and/or inspection before a subsequent processing step.

7. Apparatus according to claim 1, wherein the chamber upper wall (410) comprises a process opening (250) for receiving a process head (150) for: (i) dispensing solder onto the substrate (300) for a solder process; (ii) shaping solder on the substrate (300) for a solder process; (iii) releasably attaching to a component (600), arranged to be positioned at the first processing position (800) with the component (600); (iv) inspection of the substrate (300); inspection of a component (600); (v) inspection of the support (320); (vi) inspection after an earlier processing step; and/or (vii) inspection before a subsequent processing step, the process opening (250) being arranged to allow movement of the process head (150) towards and/or away from the first processing position (800) along the third axis (930), the third axis (930) being perpendicular to the first axis (910) and perpendicular to the second (920) axis.

8. Apparatus according to claim 7, wherein the process opening (250) and the hold-down opening (270) are separate openings in the chamber upper wall (410).

9. Apparatus according to claim 1, wherein the hold-down device (500) comprises one or more hold-down protrusions (541, 542, 1541, 1542), which are attached to the actuator member (520), wherein the one or more hold-down protrusions (541, 542, 1541, 1542) are arranged to directly exert, in use, a hold-down force received from the actuator member (520) on at least a portion of the substrate (300).

10. Apparatus according to claim 1, wherein the hold-down device (500, 501, 502) comprises a hold-down drive (560), which is arranged outside the process chamber (400) so as to exert a hold-down force on the actuator member (520).

11. Apparatus according to claim 1, wherein the hold-down device (500, 501, 502) comprises a first hold-down member (510), extending outside the processing chamber (400) along the second axis (920), arranged to exert a hold-down force on the actuator member (520).

12. Apparatus according to claim 11, wherein a first end portion of the first hold-down member (510) comprises a drive attachment (550) for attachment to a hold-down drive (560) positioned outside the processing chamber (400); wherein a second end portion of the first hold-down member (510) comprises a pivot point (570), arranged to convert, in use, at least a portion of movement of the first hold-down member (510) due to the operation of the hold-down drive (560) to a degree of rotation about the first axis (910); and wherein the attachment of the first hold-down member (510) to the actuator member (520) is arranged to convert, in use, at least a portion of the degree of rotation about the first axis (910) to a degree of movement of the actuator member (520) along the third axis (930) towards the substrate (300) at the first processing position (800), thereby exerting a hold-down force on the actuator member (520).

13. Apparatus according to claim 1, wherein the processing chamber (400) is arranged to provide, in use, one or more processing environments (700, 1700).

14. Apparatus according to claim 7, wherein the process opening (250, 1250) is arranged to provide one or more gas curtains allowing, during use, a predetermined and/or controlled flow of the gas in and/or out of one or more processing environments (700, 1700).

15. Apparatus according to claim 13, wherein the hold-down opening (270) is arranged to provide one or more gas curtains allowing, during use, a predetermined and/or controlled flow of the gas in and/or out of one or more processing environments (700, 1700).

16. Apparatus according to claim 1, wherein the processing chamber (400) comprises a chamber lower wall (420), extending along the first axis (910) and extending along the second axis (920).

17. Apparatus according to claim 16, wherein the chamber lower wall (420) and the support (320) are made integrally or positively and force-fitted to each other.

18. Apparatus according to claim 1, wherein the apparatus (100, 101, 102) comprises one or more heaters and/or one or more heating elements, arranged to raise a temperature of at least a portion of one or more processing surfaces of the substrate (300).

19. Apparatus according to claim 18, wherein the one or more heaters and/or one or more heating elements are attached to a process head (150).

20. Apparatus according to claims 18, wherein the one or more heaters and/or one or more heating elements are housed in the processing chamber (400) or attached to the processing chamber (400).

21. Apparatus according to claim 1, wherein the processing chamber (400) is arranged to receive a component (600), and wherein the substrate (300) is arranged, in use, to receive and support the component (600) during processing.

22. Apparatus according to claim 21, wherein the component is a die, semiconductor package, a chip, an integrated circuit, a substrate, or any combination thereof.

23. Apparatus according to claim 1, wherein the apparatus (100, 101, 102) comprises a media carrier, arranged to move along the first axis (910) to position the substrate at the first processing position (800).

24. Apparatus according to claim 23, wherein the media carrier and the support (320) are connected integrally or form-and force-fitted to each other.

25. Apparatus according to claim 23, wherein the media carrier is arranged to move the substrate along the first axis (910) and to position the substrate at one or more further positions for loading of the substrate, dispensing solder onto at least a part of the processing position of the substrate, distributing solder on at least a part of the processing position of the substrate, processing of the substrate and/or unloading of the substrate.

26. Apparatus according to claim 23, wherein the apparatus (100, 101, 102) comprises a process head (150). for releasably attaching to a component (600). arranged to be positioned at the first processing position (800) with the component (600). and wherein the apparatus (100, 101, 102) comprises a further process head (1150) for releasably attaching to a further component (1600), arranged to be positioned at a second processing position (805) with the further component (1600); and
wherein the media carrier is arranged to move along the first axis (910) and/or along the second axis (920) to position a further substrate (1300) at the second processing position (805).

27. Apparatus according to claim 26, wherein the hold-down device (500, 501, 502) is arranged to exert, in use, a hold-down force on at least a portion of the further substrate (1300) along the third axis (930) at the second processing position (805), wherein the further hold-down force is directly exerted, in use, from outside the processing chamber (400) on at least a portion of the one or more further substrates (1300) using the actuator member (520).
